(19) United States
(12) Patent Application Publication
(10) Pub. No.: US 2026/0341814 A1
(43) Pub. Date: Oct. 29, 2026

(54) METHOD AND APPARATUS FOR PREDICTING DEFECTS IN SECONDARY BATTERIES

(71) Applicant: Samsung SDI Co., Ltd., Yongin-si (KR)

(72) Inventors: Hyeongmin Lee, Yongin-si (KR); Jaehyeon Kim, Yongin-si (KR); Jeemin Yu, Yongin-si (KR); Haewon Lee, Yongin-si (KR)

(73) Assignee: Samsung SDI Co., Ltd., Yongin-si (KR)

(21) Appl. No.: 19/413,146

(22) Filed: Dec. 9, 2025

(30) Foreign Application Priority Data
Apr. 24, 2025 (KR) 10-2025-0053671

(51) Int. Cl. H01M 10/42; G01R 31/367

(52) U.S. Cl. CPC H01M 10/4285; G01R 31/367

(57) ABSTRACT

The present disclosure provides a method for predicting defects in a secondary battery. The method includes acquiring first data associated with a first secondary battery that has progressed up to a specific manufacturing process among a plurality of manufacturing processes for manufacturing the secondary battery, acquiring second data associated with the first data, generating synthetic data associated with the first secondary battery based on the first data and the second data, and predicting whether the first secondary battery is defective based on the synthetic data using a machine learning model, wherein the first data includes data up to the specific manufacturing process, and the second data includes data after the specific manufacturing process.

### CROSS-REFERENCE TO RELATED APPLICATIONS

This present application claims priority to and the benefit under 35 U.S.C. § 119(a)-(d) of Korean Application No. 10-2025-0053671, filed on Apr. 24, 2025, in the Korean Intellectual Property Office, the entire disclosure of which is incorporated herein by reference.

### FIELD

The present disclosure relates to a method and apparatus for predicting defects in secondary batteries.

### BACKGROUND

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

A secondary battery may be manufactured through a plurality of processes. If a secondary battery in a semi-finished state does not meet the conformity criteria of each process, the secondary battery in the semi-finished state may be discarded as a non-conforming semi-finished product. Accordingly, manufacturing costs and disposal costs for the secondary battery up to the corresponding process may be incurred. In this case, there is a problem in that the later a non-conforming semi-finished product is detected in the manufacturing process, the higher the manufacturing cost of the secondary battery incurred in subsequent processes and the disposal cost of the secondary battery that has progressed closer to a finished product.

The herein information disclosed in this Background section is for enhancement of understanding of the background of the present disclosure, and therefore, it may contain information that does not constitute related (or prior) art.

### SUMMARY

The present disclosure provides a method and apparatus for predicting defects in a secondary battery to solve the herein technical problem.

These and other aspects and features of the present disclosure will be described in or will be apparent from the following description of embodiments of the present disclosure.

According to embodiments of the present disclosure, a method for predicting defects in a secondary battery includes acquiring first data associated with a first secondary battery that has progressed up to a specific manufacturing process among a plurality of manufacturing processes for manufacturing the secondary battery, acquiring second data associated with the first data, generating synthetic data associated with the first secondary battery based on the first data and the second data, and predicting whether the first secondary battery is defective based on the synthetic data using a machine learning model, wherein the first data includes data up to the specific manufacturing process, and the second data includes data after the specific manufacturing process.

According to embodiments of the present disclosure, an apparatus includes a communication module, a memory, and at least one processor connected to the memory and configured to execute at least one computer-readable program included in the memory, wherein the at least one program includes instructions for acquiring first data associated with a first secondary battery that has progressed up to a specific manufacturing process among a plurality of manufacturing processes for manufacturing the secondary battery, acquiring second data associated with the first data, generating synthetic data associated with the first secondary battery based on the first data and the second data, and predicting whether the first secondary battery is defective based on the synthetic data using a machine learning model, wherein the first data includes data up to the specific manufacturing process, and the second data includes data after the specific manufacturing process.

According to some embodiments of the present disclosure, whether a secondary battery being manufactured in real time is defective may be predicted in advance. Accordingly, by discarding a secondary battery in a non-conforming semi-finished state, manufacturing costs and disposal costs that may be incurred in subsequent processes may be reduced. Furthermore, the defect rate of manufactured secondary batteries may be reduced.

According to some embodiments of the present disclosure, not only the manufacturing history data of a specific process among a plurality of manufacturing processes but also the manufacturing history data of the entire plurality of manufacturing processes may be utilized. Accordingly, the accuracy and reliability of the synthetic data used for predicting defects in the secondary battery may be improved.

However, aspects and features of the present disclosure are not limited to those described herein, and other aspects and features not mentioned will be clearly understood by a person skilled in the art from the detailed description, described herein.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 illustrates an example of a method for predicting defects in a secondary battery according to embodiments of the present disclosure.

FIG. 2 is a schematic diagram illustrating a configuration in which an information processing system is communicably connected with a plurality of user terminals to predict defects in a secondary battery according to embodiments of the present disclosure.

FIG. 3 is a block diagram illustrating the internal configuration of a user terminal and an information processing system according to embodiments of the present disclosure.

FIG. 4 illustrates an example of data for generating synthetic data according to embodiments of the present disclosure.

FIG. 5 illustrates an example of parameters for each process according to embodiments of the present disclosure.

FIG. 6 illustrates an example of a method for generating synthetic data according to embodiments of the present disclosure.

FIG. 7 illustrates an example of a machine learning model according to embodiments of the present disclosure.

FIG. 8 illustrates an example of a method for determining whether a secondary battery is defective according to embodiments of the present disclosure.

FIG. 9 illustrates an example of a graph showing a plurality of predicted values according to embodiments of the present disclosure.

FIG. 10 illustrates an example of a method for determining whether a secondary battery is defective according to embodiments of the present disclosure.

FIG. 11 illustrates an example of a graph showing a plurality of predicted values according to embodiments of the present disclosure.

FIG. 12 illustrates an example of a response method when it is determined that a secondary battery is defective according to embodiments of the present disclosure.

FIG. 13 is a flowchart illustrating an example of a method for predicting defects in a secondary battery according to embodiments of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her disclosure in the best way.

The embodiments described in this specification and the configurations shown in the drawings are only some of the embodiments of the present disclosure and do not represent all of the technical ideas, aspects, and features of the present disclosure.

Accordingly, it should be understood that there may be various equivalents and modifications that can replace or modify the embodiments described herein at the time of filing this application.

It will be understood that when a layer or element is referred to as being “between” two layers, it can be the only layer between the two layers, or one or more intervening layers may also be present. It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed herein could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of local patent laws.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

In the present disclosure, the sizes and relative sizes of layers and regions shown in the drawings may be exaggerated for clarity of description. That is, the sizes shown in the drawings are for convenience of understanding and are not limited thereto. In addition, throughout the specification, the same reference numerals refer to the same components.

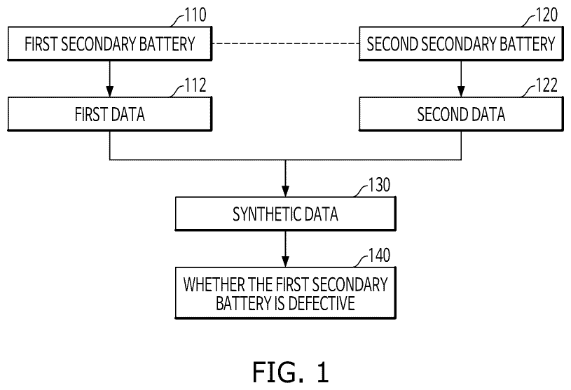

FIG. 1 illustrates an example of a method for predicting defects in a secondary battery according to embodiments of the present disclosure.

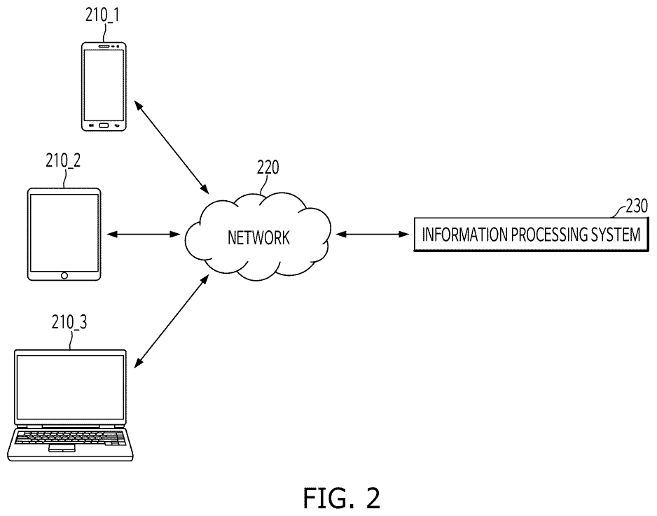

Referring to FIG. 1, in embodiments, a processor (for example, at least one processor of the information processing system to be described later with reference to FIG. 2) may acquire a first data 112 associated with a first secondary battery 110 that has progressed up to a specific manufacturing process among a plurality of manufacturing processes for manufacturing a secondary battery. Here, the first data 112 may include data up to the specific manufacturing process of the first secondary battery 110 in a semi-finished state. For example, if the manufacturing of the first secondary battery 110 has progressed up to a second process among a plurality of manufacturing processes, the first data 112 may include manufacturing history data up to the second process.

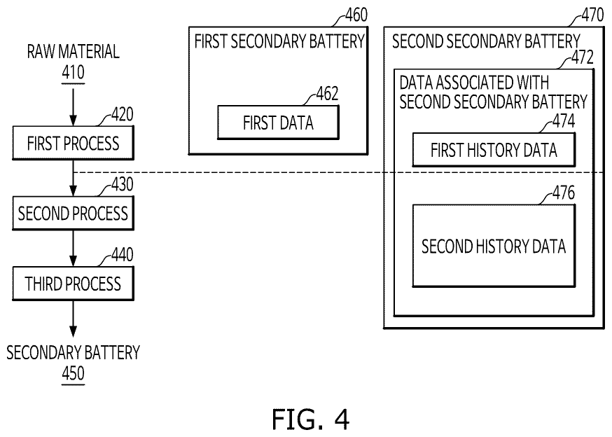

In, the processor may acquire a second data 122 associated with the first data 112. Specifically, the second data 122 may include at least a portion of data associated with a second secondary battery 120 that is different from the first secondary battery 110. Here, the second secondary battery 120 may correspond to a secondary battery in a finished state. In addition, the data associated with the second secondary battery 120 may include a first history data up to the specific manufacturing process of the second secondary battery 120 and a second history data after the specific manufacturing process of the second secondary battery 120. In this case, the processor may compare the first data 112 of the first secondary battery 110 with the first history data of the second secondary battery 120. Furthermore, the processor may acquire the second history data as the second data 122 based on a result of comparing the first data 112 and the first history data. The second data 122 may include data after the specific manufacturing process. An example of acquiring the second data 122 will be described in detail later with reference to FIGS. 4-6.

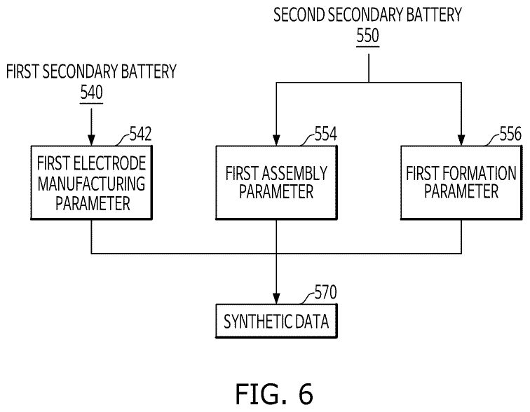

In embodiments, the processor may generate a synthetic data 130 associated with the first secondary battery 110 based on the first data 112 and the second data 122. Here, the synthetic data 130 may be data in which the manufacturing history data up to the specific manufacturing process where the manufacturing of the first secondary battery 110 has progressed and the manufacturing history data after the specific manufacturing process where the manufacturing of the second secondary battery 120 has progressed are synthesized. In addition, the synthetic data 130 may include a plurality of synthetic data associated with the first secondary battery 110. An example of the synthetic data 130 will be described in detail later with reference to FIG. 6.

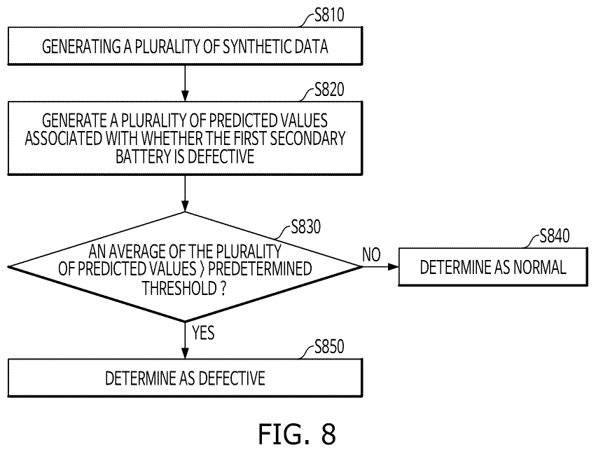

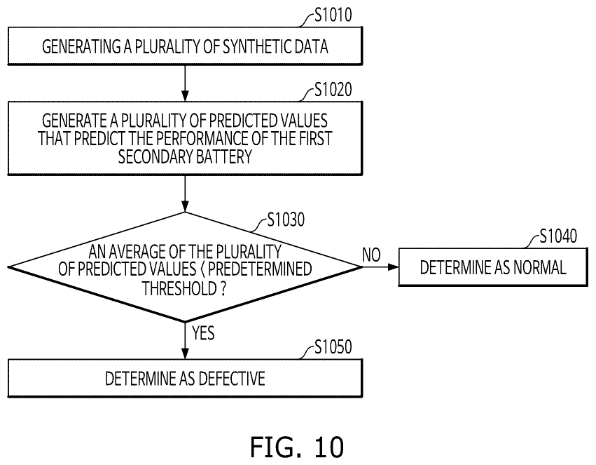

In embodiments, the processor may predict whether the first secondary battery 110 is defective 140 based on the synthetic data 130 using a machine learning model. Specifically, the processor may use the machine learning model to generate a plurality of predicted values associated with whether the first secondary battery 110 is defective for each of the plurality of synthetic data. For example, the processor may use the machine learning model to generate a probability that the first secondary battery 110 is defective for each of the plurality of synthetic data. In this case, the processor may determine whether the first secondary battery 110 is defective 140 based on the plurality of predicted values. An example of determining whether the first secondary battery 110 is defective 140 will be described in detail later with reference to FIGS. 8 and 10.

In embodiments, based on the predicted defect status 140 of the first secondary battery 110, the processor may determine whether to proceed with a manufacturing process after the specific manufacturing process of the first secondary battery 110. For example, if the processor predicts that the first secondary battery 110 is defective, the processor may decide to discard the first secondary battery 110 as a non-conforming semi-finished product. In addition, the processor may provide guidance associated with the first secondary battery 110. Here, the guidance associated with the first secondary battery 110 may include at least one of identification data, location data, manufacturing process data, quality data of the first secondary battery 110, data associated with equipment for manufacturing the first secondary battery 110, or data associated with the manufacturing environment of the first secondary battery 110.

With this configuration, whether a secondary battery being manufactured in real time is defective may be predicted in advance. Accordingly, by discarding a secondary battery in a non-conforming semi-finished state, manufacturing costs and disposal costs that may be incurred in subsequent processes may be reduced. Furthermore, the defect rate of manufactured secondary batteries may be reduced.

FIG. 2 is a schematic diagram illustrating a configuration in which an information processing system 230 is communicably connected with a plurality of user terminals 210_1, 210_2, and 210_3 to predict defects in a secondary battery according to embodiments of the present disclosure.

As illustrated, a plurality of user terminals 210_1, 210_2, and 210_3 may be connected via a network 220 to an information processing system 230 that may provide a secondary battery defect prediction service. Here, the plurality of user terminals 210_1, 210_2, and 210_3 may include terminals of users who are provided with the secondary battery defect prediction service.

In embodiments, the information processing system 230 may include one or more server devices and/or databases, or one or more distributed computing devices and/or distributed databases based on a cloud computing service, which may store, provide, and execute computer-executable programs (e.g., downloadable applications) and data associated with providing a secondary battery defect prediction service.

The secondary battery defect prediction service provided by the information processing system 230 may be provided to a user through a secondary battery defect prediction application, a web browser, a web browser extension program, etc. installed on each of the plurality of user terminals 210_1, 210_2, and 210_3. For example, the information processing system 230 may provide information corresponding to a secondary battery defect prediction request received from the user terminals 210_1, 210_2, and 210_3 through a secondary battery defect prediction application, or perform corresponding processing.

The plurality of user terminals 210_1, 210_2, and 210_3 may communicate with the information processing system 230 via the network 220. The network 220 may be configured to enable communication between the plurality of user terminals 210_1, 210_2, and 210_3 and the information processing system 230. The network 220 may be configured with a wired network such as Ethernet, Power Line Communication, a telephone line communication device, and RS-serial communication, a wireless network such as a mobile communication network, Wireless LAN (WLAN), Wi-Fi, Bluetooth, and ZigBee, or a combination thereof, depending on the installation environment. The communication method is not limited, and may include not only communication methods utilizing a communication network that the network 220 may include (e.g., mobile communication network, wired internet, wireless internet, broadcasting network, satellite network, etc.) but also short-range wireless communication between the user terminals 210_1, 210_2, and 210_3.

In FIG. 2, a mobile phone terminal 210_1, a tablet terminal 210_2, and a PC terminal 210_3 are illustrated as examples of user terminals, but the present disclosure is not limited thereto, and the user terminals 210_1, 210_2, and 210_3 may be any computing device capable of wired and/or wireless communication and on which a secondary battery defect prediction application or a web browser may be installed and executed. For example, the user terminal may include an AI speaker, a smartphone, a mobile phone, a navigation system, a computer, a laptop, a digital broadcasting terminal, a Personal Digital Assistant (PDA), a Portable Multimedia Player (PMP), a tablet PC, a game console, a wearable device, an Internet of Things (IOT) device, a virtual reality (VR) device, an augmented reality (AR) device, a set-top box, etc. In addition, although FIG. 2 illustrates three user terminals 210_1, 210_2, and 210_3 communicating with the information processing system 230 via the network 220, the present disclosure is not limited thereto, and a different number of user terminals may be configured to communicate with the information processing system 230 via the network 220.

In FIG. 2, a configuration in which a user's request (e.g., a secondary battery defect prediction request) is transmitted to the information processing system 230 through the user terminals 210_1, 210_2, and 210_3 is exemplarily illustrated, but the present disclosure is not limited thereto, and the user's request may be provided to the information processing system 230 through an input device associated with the information processing system 230 without passing through the user terminals 210_1, 210_2, and 210_3, and a result of processing the user's request (e.g., a secondary battery defect prediction) may be provided to the user through an output device (e.g., a display, etc.) associated with the information processing system 230.

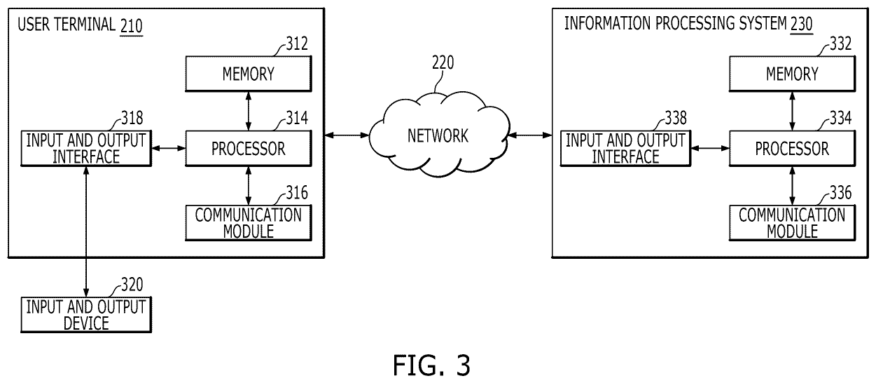

FIG. 3 is a block diagram illustrating the internal configuration of a user terminal 210 and an information processing system 230 according to embodiments of the present disclosure.

The user terminal 210 may refer to any computing device on which an application, a web browser, etc. can be executed and which is capable of wired/wireless communication, and may include, for example, the mobile phone terminal 210_1, the tablet terminal 210_2, the PC terminal 210_3, etc. of FIG. 2. As illustrated, the user terminal 210 may include a memory 312, a processor 314, a communication module 316, and an input/output interface 318. Similarly, the information processing system 230 may include a memory 332, a processor 334, a communication module 336, and an input/output interface 338. As illustrated in FIG. 3, the user terminal 210 and the information processing system 230 may be configured to communicate information and/or data via the network 220 using their respective communication modules 316 and 336. In addition, an input/output device 320 may be configured to input information and/or data to the user terminal 210 through the input/output interface 318 or to output information and/or data generated from the user terminal 210.

The memories 312 and 332 may include any non-transitory computer-readable recording medium. According to embodiments, the memories 312 and 332 may include a permanent mass storage device such as a read-only memory (ROM), a disk drive, a solid state drive (SSD), a flash memory, etc. As another example, a non-volatile mass storage device such as a ROM, SSD, flash memory, disk drive, etc. may be included in the user terminal 210 or the information processing system 230 as a separate permanent storage device distinct from the memory. In addition, an operating system and at least one program code may be stored in the memories 312 and 332. In embodiments, the memories 312 and 332 may store manufacturing history data associated with a secondary battery in a semi-finished state during manufacturing and manufacturing history data associated with a secondary battery in a finished state with manufacturing completed.

These software components may be loaded from a computer-readable recording medium separate from the memories 312 and 332. Such a separate computer-readable recording medium may include a recording medium that can be directly connected to the user terminal 210 and the information processing system 230, for example, a computer-readable recording medium such as a floppy drive, disk, tape, DVD/CD-ROM drive, memory card, etc. As another example, the software components may be loaded into the memories 312 and 332 through the communication modules 316 and 336 rather than a computer-readable recording medium. For example, at least one program may be loaded into the memories 312 and 332 based on a computer program installed by files provided through the network 220 by developers or a file distribution system that distributes installation files of an application.

The processors 314 and 334 may be configured to process instructions of a computer program by performing basic arithmetic, logic, and input/output operations. The instructions may be provided to the processors 314 and 334 by the memories 312 and 332 or the communication modules 316 and 336. For example, the processors 314 and 334 may be configured to execute received instructions according to program code stored in a recording device such as the memories 312 and 332.

The communication modules 316 and 336 may provide a configuration or function for the user terminal 210 and the information processing system 230 to communicate with each other via the network 220, and may provide a configuration or function for the user terminal 210 and/or the information processing system 230 to communicate with another user terminal or another system (e.g., a separate cloud system, etc.). As an example, a request or data (e.g., a secondary battery defect prediction request, etc.) generated by the processor 314 of the user terminal 210 according to program code stored in a recording device such as the memory 312 may be transmitted to the information processing system 230 via the network 220 under the control of the communication module 316. Conversely, a control signal or command provided under the control of the processor 334 of the information processing system 230 may be received by the user terminal 210 through the communication module 316 of the user terminal 210 via the communication module 336 and the network 220.

The input/output interface 318 may be a means for interfacing with the input/output device 320. As an example, the input device may include a device such as a camera including an audio sensor and/or an image sensor, a keyboard, a microphone, a mouse, etc., and the output device may include a device such as a display, a speaker, a haptic feedback device, etc. As another example, the input/output interface 318 may be a means for interfacing with a device in which a configuration or function for performing input and output, such as a touchscreen, is integrated into one. For example, a service screen configured using information and/or data provided by the information processing system 230 or another user terminal while the processor 314 of the user terminal 210 processes instructions of a computer program loaded into the memory 312 may be displayed on a display through the input/output interface 318. Although FIG. 3 illustrates the input/output device 320 as not being included in the user terminal 210, the present disclosure is not limited thereto, and the input/output device 320 may be configured as a single device with the user terminal 210. In addition, the input/output interface 338 of the information processing system 230 may be a means for interfacing with a device (not shown) for input or output that is connected to or may be included in the information processing system 230. Although FIG. 3 illustrates the input/output interfaces 318 and 338 as elements configured separately from the processors 314 and 334, the present disclosure is not limited thereto, and the input/output interfaces 318 and 338 may be configured to be included in the processors 314 and 334.

The user terminal 210 and the information processing system 230 may include more components than the components of FIG. 3. In embodiments, the user terminal 210 may be implemented to include at least some of the input/output devices 320 described herein. In addition, the user terminal 210 may further include other components such as a transceiver, a Global Positioning System (GPS) module, a camera, various sensors, a database, etc. For example, if the user terminal 210 is a smartphone, the user terminal 210 may include components that a smartphone generally includes, and for example, various components such as an acceleration sensor, a gyro sensor, a microphone module, a camera module, various physical buttons, buttons using a touch panel, input/output ports, a vibrator for vibration, etc. may be implemented to be further included in the user terminal 210.

While a program or application for secondary battery defect prediction is operating, the processor 314 may receive text, images, videos, voice, and/or motions input or selected through an input device such as a touchscreen, a keyboard, a camera including an audio sensor and/or an image sensor, a microphone, etc. connected to the input/output interface 318, and may store the received text, images, videos, voice, and/or motions in the memory 312 or provide them to the information processing system 230 via the communication module 316 and the network 220.

The processor 314 of the user terminal 210 may be configured to manage, process, and/or store information and/or data received from the input/output device 320, other user terminals, the information processing system 230, and/or a plurality of external systems. The information and/or data processed by the processor 314 may be provided to the information processing system 230 via the communication module 316 and the network 220. The processor 314 of the user terminal 210 may transmit information and/or data to the input/output device 320 via the input/output interface 318 to be output. For example, the processor 314 may output or display the received information and/or data on a screen associated with the user terminal 210.

The processor 334 of the information processing system 230 may be configured to manage, process, and/or store information and/or data received from the plurality of user terminals 210 and/or a plurality of external systems. The information and/or data processed by the processor 334 may be provided to the user terminal 210 via the communication module 336 and the network 220.

FIG. 4 illustrates an example of data for generating synthetic data according to embodiments of the present disclosure.

Referring to FIG. 4, in embodiments, a secondary battery 450 may be manufactured by performing a plurality of manufacturing processes such as a first process 420, a second process 430, and a third process 440 using a raw material 410. Here, the plurality of processes may include at least one of an electrode manufacturing process for manufacturing an electrode, an assembly process for assembling components of the secondary battery 450 (e.g., an electrode assembly including the electrode, a case, an electrode terminal, etc.), or a formation process for performing formation of the secondary battery 450, but is not limited thereto, and the plurality of manufacturing processes may be further subdivided.

In embodiments, a processor (e.g., 334 of FIG. 3) may acquire a first data 462 associated with a first secondary battery 460 that has progressed up to a specific manufacturing process (e.g., the first process 420, etc.) among a plurality of manufacturing processes for manufacturing the secondary battery 450. Here, the first secondary battery 460 corresponds to a secondary battery in a semi-finished state, and the first data 462 may include data up to the specific manufacturing process.

In embodiments, the first data 462, as manufacturing history data, may include data associated with a measurement parameter according to each unit process up to the specific manufacturing process. The first data 462 may include at least one of data associated with the quality of the first secondary battery 460 up to the specific manufacturing process or data associated with the manufacturing environment of the first secondary battery 460. For example, if the specific manufacturing process is an electrode manufacturing process, the data associated with the quality of the first secondary battery 460 may include the width, thickness, exit angle, length, and tilt angle of the electrode, and the data associated with the manufacturing environment of the first secondary battery 460 may include the temperature of a drying furnace for drying the electrode, the motor current of the drying furnace, valve pressure, valve speed, the position value of the electrode, steam flow rate, process time, etc. As another example, if the specific manufacturing process is an assembly process, the data associated with the quality of the first secondary battery 460 may include the degree of alignment of an assembly, height difference, flatness, electrolyte injection amount, electrolyte impregnation time, thickness before/after sealing, weight before/after electrolyte injection, degree of vacuum, etc., and the data associated with the manufacturing environment of the first secondary battery 460 may include assembly bead area, flow rate and flow velocity of a current collector, jig pressure, power of a cutter and a laser, flow velocity of a dust collector, process time, etc. As yet another example, if the specific manufacturing process is a formation process, the data associated with the quality of the first secondary battery 460 may include charging current, charging voltage, degassing vacuum level, temperature of the first secondary battery 460, thickness, deviation before/after vacuum, OCV, IR, etc. in the formation process, and the data associated with the manufacturing environment of the first secondary battery 460 may include the tray temperature of the formation process, process time, preheating time, presence of process defects, vision measurement results, etc.

In embodiments, the processor may acquire a second data associated with the first data 462. Here, the second data may include at least a portion of a data 472 associated with a second secondary battery 470 that is different from the first secondary battery 460. In addition, the second secondary battery 470 may correspond to a secondary battery in a finished state. Additionally, the second secondary battery 470 and the first secondary battery 460 may be identical or similar in at least one of their type, manufacturing date, weather, or temperature.

In embodiments, the data 472 associated with the second secondary battery 470 may include a first history data 474 up to a specific manufacturing process of the second secondary battery 470 and a second history data 476 after the specific manufacturing process. Here, the first history data 474 may include data associated with the quality of the second secondary battery 470 up to the specific manufacturing process and data associated with the manufacturing environment of the second secondary battery 470. In addition, the second history data 476 may include data associated with the quality of the second secondary battery 470 after the specific manufacturing process and data associated with the manufacturing environment of the second secondary battery 470.

In embodiments, the processor may compare the first data 462 of the first secondary battery 460 that has progressed up to a specific manufacturing process (e.g., the first process 420) with the first history data 474 of the second secondary battery 470 that has progressed up to the specific manufacturing process. Furthermore, the processor may acquire the second history data 476 as the second data based on a result of comparing the first data 462 and the first history data 474. Specifically, the processor may acquire the second history data 476 as the second data if the first data 462 and the first history data 474 are identical or similar. For example, if the measurement parameter of the first secondary battery 460 and the measurement parameter of the second secondary battery 470 in the specific manufacturing process are identical or similar, the processor may acquire the second history data 476 as the second data. Here, that the measurement parameters are similar may mean that a difference between the measurement parameters is within a predetermined threshold.

In FIG. 4, for convenience of explanation, the plurality of manufacturing processes are illustrated as including the first process 420, the second process 430, and the third process 440, but the present disclosure is not limited thereto, and the plurality of manufacturing processes may include additional processes. In addition, although FIG. 4 illustrates that the first secondary battery 460 has progressed up to the first process 420, the present disclosure is not limited thereto. If the first secondary battery 460 has progressed up to the second process 430, the first history data 474 of the second secondary battery 470 may include manufacturing history data of the second secondary battery 470 that has progressed up to the second process 430.

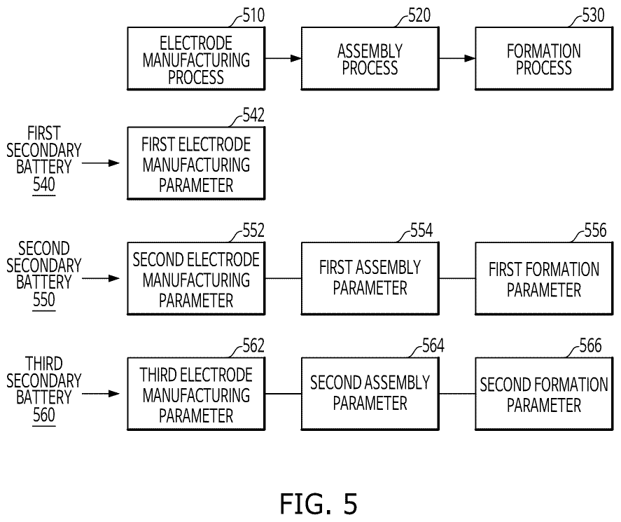

FIG. 5 illustrates an example of parameters for each process according to embodiments of the present disclosure, and FIG. 6 illustrates an example of a method for generating a synthetic data 570 according to embodiments of the present disclosure.

In embodiments, referring to FIG. 5, the plurality of manufacturing processes for manufacturing a secondary battery may include an electrode manufacturing process 510 for manufacturing an electrode required for the secondary battery, an assembly process 520 for assembling components such as the electrode, a case, and an electrode terminal, and a formation process 530 for performing formation of the assembled secondary battery. According to this plurality of manufacturing processes, manufacturing history data for each manufacturing process may be generated. This manufacturing history data may include data associated with measurement parameters used in each of the manufacturing processes. For example, in the electrode manufacturing process 510, electrode manufacturing parameters used for electrode manufacturing may be generated, in the assembly process 520, assembly parameters used for assembling components may be generated, and in the formation process 530, formation parameters used for performing formation of the assembled secondary battery may be generated.

In embodiments, a processor (e.g., 334 of FIG. 3) may acquire a first data associated with a first secondary battery 540 that has progressed up to a specific manufacturing process among a plurality of manufacturing processes for manufacturing a secondary battery. Here, the first secondary battery 540 corresponds to a secondary battery in a semi-finished state, and the first data may include data up to the specific manufacturing process. For example, if the first secondary battery 540 has progressed up to the electrode manufacturing process 510, the first data may include a first electrode manufacturing parameter 542.

In embodiments, the processor may acquire a second data associated with the first data of the first secondary battery 540. Here, the second data may include at least a portion of data associated with a second secondary battery 550, which is different from the first secondary battery 540 and corresponds to a secondary battery in a finished state. In addition, the data associated with the second secondary battery 550 may include a first history data up to a specific manufacturing process of the second secondary battery 550 and a second history data after the specific manufacturing process. For example, if the first secondary battery 540 has progressed up to the electrode manufacturing process 510, the first history data of the second secondary battery 550 includes a second electrode manufacturing parameter 552 generated in the electrode manufacturing process 510, and the second history data may include a first assembly parameter 554 and a first formation parameter 556 generated in processes after the electrode manufacturing process 510.

In embodiments, the second data may include data associated with a plurality of secondary batteries that have undergone all of the plurality of manufacturing processes. For example, the second data may include not only data associated with the second secondary battery 550 but also at least a portion of data associated with a third secondary battery 560, which is different from the first secondary battery 540 and corresponds to a secondary battery in a finished state. Here, the data associated with the third secondary battery 560 may include a third history data up to a specific manufacturing process of the third secondary battery 560 and a fourth history data after the specific manufacturing process. For example, if the first secondary battery 540 has progressed up to the electrode manufacturing process 510, the third history data of the third secondary battery 560 includes a third electrode manufacturing parameter 562 generated in the electrode manufacturing process 510, and the fourth history data may include a second assembly parameter 564 and a second formation parameter 566 generated in processes after the electrode manufacturing process 510.

In embodiments, the processor may compare the first data of the first secondary battery 540 with the first history data of the second secondary battery 550. Furthermore, the processor may acquire the second history data as the second data based on a result of comparing the first data and the first history data. For example, if the first electrode manufacturing parameter 542 of the first secondary battery 540 and the second electrode manufacturing parameter 552 of the second secondary battery 550 are identical or similar, the processor may acquire the second history data of the second secondary battery 550 as the second data. As another example, if the first electrode manufacturing parameter 542 of the first secondary battery 540 and the third electrode manufacturing parameter 562 of the third secondary battery 560 are not identical or similar, the processor may determine not to acquire the fourth history data of the third secondary battery 560 as the second data. In this way, the processor may filter the history data for at least a portion of the plurality of secondary batteries by comparing the first data of the first secondary battery 540 in a semi-finished state with the history data of the plurality of secondary batteries in a finished state.

In embodiments, referring to FIG. 6, the processor may generate a synthetic data 570 associated with the first secondary battery 540 based on the first data of the first secondary battery 540 and the second data associated with a secondary battery different from the first secondary battery 540. For example, if it is determined that the first data of the first secondary battery 540 and the first history data of the second secondary battery 550 are identical or similar, the processor may acquire the second history data of the second secondary battery 550 as the second data. In this case, the processor may synthesize the first data of the first secondary battery 540 and the second history data of the second secondary battery 550. For example, the processor may generate the synthetic data 570 by synthesizing the first electrode manufacturing parameter 542 of the first secondary battery 540 generated in the electrode manufacturing process 510, and the first assembly parameter 554 and the first formation parameter 556 of the second secondary battery 550 generated in the assembly process 520 and the formation process 530, which are manufacturing processes after the electrode manufacturing process 510.

In embodiments, the synthetic data 570 may include a plurality of synthetic data associated with the first secondary battery 540. Specifically, there may exist a plurality of secondary batteries that include history data identical or similar to the first data of the first secondary battery 540. The processor may generate the plurality of synthetic data associated with the first secondary battery 540 by filtering out secondary batteries that do not include history data identical or similar to the first data of the first secondary battery 540 and using the history data of the remaining filtered secondary batteries.

In FIGS. 5 and 6, it has been described that measurement parameters according to large-scale processes such as the electrode manufacturing process 510, the assembly process 520, and the formation process 530 are used, but the present disclosure is not limited thereto. For example, even when a small-scale process such as measuring the length, temperature, weight, etc. of a semi-finished product within a large-scale process is performed on the first secondary battery 540, the processor may generate the synthetic data 570 based on the history data of a secondary battery in a finished state that is identical or similar to the measurement parameters for each small-scale process of the first secondary battery 540.

With this configuration, not only the manufacturing history data of a specific process among a plurality of manufacturing processes but also the manufacturing history data of the entire plurality of manufacturing processes may be utilized. Accordingly, the accuracy and reliability of the synthetic data used for predicting defects in the secondary battery may be improved.

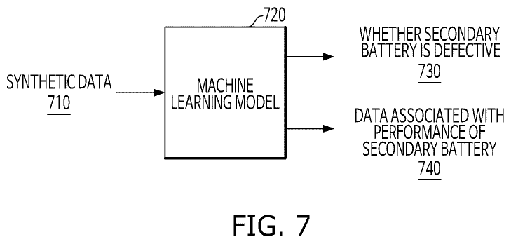

FIG. 7 illustrates an example of a machine learning model 720 according to embodiments of the present disclosure.

In embodiments, a processor (e.g., 334 of FIG. 3) may predict whether a secondary battery is defective 730 based on a synthetic data (e.g., 570 of FIG. 6) 710. Specifically, the processor may use a machine learning model 720 to predict whether the secondary battery corresponding to a semi-finished state is defective 730 based on the synthetic data 710. Here, the machine learning model 720 may be trained to take the synthetic data 710 associated with the secondary battery corresponding to the semi-finished state as input, and predict and output whether the secondary battery is defective 730 when the manufacturing of the corresponding secondary battery is completed. In addition, the machine learning model 720 may correspond to a model trained on a dataset including data associated with a secondary battery that has undergone all of the plurality of manufacturing processes and information on whether the corresponding secondary battery is defective. For example, the machine learning model 720 may, based on the synthetic data 710 associated with the secondary battery in the semi-finished state, predict and output whether the manufactured secondary battery is defective 730 when the manufacturing of the corresponding secondary battery is completed.

In embodiments, the synthetic data 710 may include a plurality of synthetic data associated with the secondary battery. In this case, the processor may use the machine learning model 720 to generate a plurality of predicted values associated with whether the secondary battery is defective for each of the plurality of synthetic data. Furthermore, the processor may determine whether the secondary battery is defective based on the plurality of predicted values. Specifically, the plurality of predicted values may include the probability that the secondary battery is defective for each of the plurality of synthetic data. In addition, if an average of the predicted values that predict the secondary battery is defective among the plurality of predicted values is higher than a predetermined threshold (e.g., 50%), the processor may determine the secondary battery in the semi-finished state to be defective.

In embodiments, the processor may use the machine learning model 720 to predict the performance of the secondary battery corresponding to the semi-finished state based on the synthetic data 710. Here, the machine learning model 720 may be trained to take the synthetic data 710 associated with the secondary battery corresponding to the semi-finished state as input, and predict the performance of the secondary battery and output a data 740 associated with the performance of the secondary battery when the manufacturing of the corresponding secondary battery is completed. In addition, the machine learning model 720 may correspond to a model trained on a dataset including data associated with a secondary battery that has undergone all of the plurality of manufacturing processes and data associated with the performance of the corresponding secondary battery.

In embodiments, the processor may use the machine learning model 720 to generate a plurality of predicted values that predict the performance of the secondary battery for each of the plurality of synthetic data. Furthermore, the processor may determine whether the corresponding secondary battery is defective based on the plurality of predicted values. Specifically, each of the plurality of predicted values may include a value predicting the capacity of the secondary battery for each of the plurality of synthetic data. In this case, if an average of the plurality of predicted values that predict the capacity of the secondary battery is lower than a predetermined threshold (e.g., the capacity standard of a finished product, etc.), the processor may determine the secondary battery in the semi-finished state to be defective.

FIG. 8 illustrates an example of a method for determining whether a secondary battery is defective according to embodiments of the present disclosure.

Referring to FIG. 8, in embodiments, the method for determining whether a secondary battery is defective may begin with a processor (e.g., 334 of FIG. 3) generating a plurality of synthetic data associated with a first secondary battery (S810). Specifically, the processor may acquire a first data associated with the first secondary battery that has progressed up to a specific manufacturing process among a plurality of manufacturing processes for manufacturing the secondary battery. In addition, the processor may acquire a second data associated with the first data. Here, the first data may include history data of the first secondary battery up to the specific manufacturing process, and the second data may include history data of a second secondary battery after the specific manufacturing process. In addition, the second secondary battery may be different from the first secondary battery and may correspond to a secondary battery in a finished state. Additionally, the processor may generate the synthetic data associated with the first secondary battery based on the first data and the second data.

Thereafter, the processor may use a machine learning model (e.g., 720 of FIG. 7) to generate a plurality of predicted values associated with whether the first secondary battery is defective for each of the plurality of synthetic data (S820). Here, the plurality of predicted values associated with whether the first secondary battery is defective may include a probability that the first secondary battery will be defective when manufacturing is completed.

Thereafter, the processor may determine whether an average of the plurality of predicted values is higher than a predetermined threshold (S830). If the average of the plurality of predicted values is less than or equal to the predetermined threshold, the processor may determine that the first secondary battery is normal (S840). In this case, a subsequent manufacturing process of the first secondary battery may proceed. If the average of the plurality of predicted values is higher than the predetermined threshold, the processor may determine that the first secondary battery is defective (S850). In this case, the subsequent manufacturing process of the first secondary battery may be stopped, and it may be determined to discard the first secondary battery.

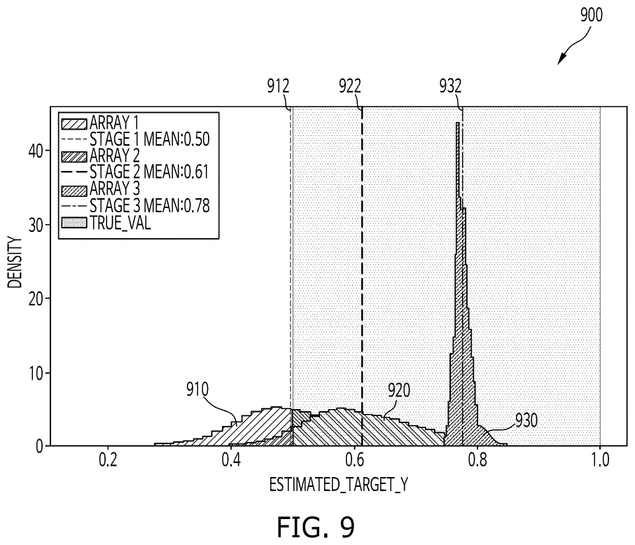

FIG. 9 illustrates an example of a graph 900 showing a plurality of predicted values according to embodiments of the present disclosure.

Referring to FIG. 9, the graph 900 shows the results of a simulation that predicted whether a secondary battery is defective using the history data of a secondary battery determined to be defective. The horizontal axis of the graph 900 represents the predicted defect probability of the secondary battery, and the vertical axis represents the density of the distribution.

In embodiments, a plurality of predicted values associated with whether a secondary battery is defective may be generated for each of a plurality of synthetic data associated with the secondary battery in a semi-finished state. The plurality of predicted values associated with a defect in the secondary battery may include a probability that the secondary battery in a finished state with manufacturing completed will be defective. In addition, if an average of the predicted values that predict the secondary battery is defective among the plurality of predicted values is higher than a predetermined threshold (e.g., 0.5 or 50%), the corresponding secondary battery may be determined to be defective.

Referring to the graph 900, a first distribution 910 represents a plurality of predicted values associated with whether a secondary battery is defective, generated based on synthetic data associated with the secondary battery in a semi-finished state up to a first process (e.g., an electrode manufacturing process). A second distribution 920 represents a plurality of predicted values associated with whether a secondary battery is defective, generated based on synthetic data associated with the secondary battery in a semi-finished state up to the first process and a second process (e.g., an assembly process). A third distribution 930 represents a plurality of predicted values associated with whether a secondary battery is defective, generated based on synthetic data associated with the secondary battery in a semi-finished state up to the first process, the second process, and a third process (e.g., a formation process). It can be confirmed that an average 922 of the second distribution 920 is located closer to 1.0 (i.e., 100% defect probability) than an average 912 of the first distribution 910. Similarly, it can be confirmed that an average 932 of the third distribution 930 is located closer to 1.0 than the average 922 of the second distribution 920. As the manufacturing process of the secondary battery proceeds, the accuracy of the defect prediction for the secondary battery may improve.

FIG. 10 illustrates an example of a method for determining whether a secondary battery is defective according to embodiments of the present disclosure.

Referring to FIG. 10, in embodiments, the method for determining whether a secondary battery is defective may begin with a processor (e.g., 334 of FIG. 3) generating a plurality of synthetic data associated with a first secondary battery (S1010). Specifically, the processor may acquire a first data associated with the first secondary battery that has progressed up to a specific manufacturing process among a plurality of manufacturing processes for manufacturing the secondary battery. In addition, the processor may acquire a second data associated with the first data. Here, the first data may include history data of the first secondary battery up to the specific manufacturing process, and the second data may include history data of a second secondary battery after the specific manufacturing process. In addition, the second secondary battery may be different from the first secondary battery and may correspond to a secondary battery in a finished state. Additionally, the processor may generate the synthetic data associated with the first secondary battery based on the first data and the second data.

Thereafter, the processor may use a machine learning model (e.g., 720 of FIG. 7) to generate a plurality of predicted values that predict the performance of the first secondary battery for each of the plurality of synthetic data (S1020). Here, the plurality of predicted values that predict the performance of the first secondary battery may include values that predict the capacity of the first secondary battery when manufacturing is completed.

Thereafter, the processor may determine whether an average of the plurality of predicted values that predict the capacity of the first secondary battery is lower than a predetermined threshold (S1030). If the average of the plurality of predicted values is greater than or equal to the predetermined threshold, the processor may determine that the first secondary battery is normal (S1040). In this case, a subsequent manufacturing process of the first secondary battery may proceed. If the average of the plurality of predicted values is lower than the predetermined threshold, the processor may determine that the first secondary battery is defective (S1050). In this case, the subsequent manufacturing process of the first secondary battery may be stopped, and it may be determined to discard the first secondary battery.

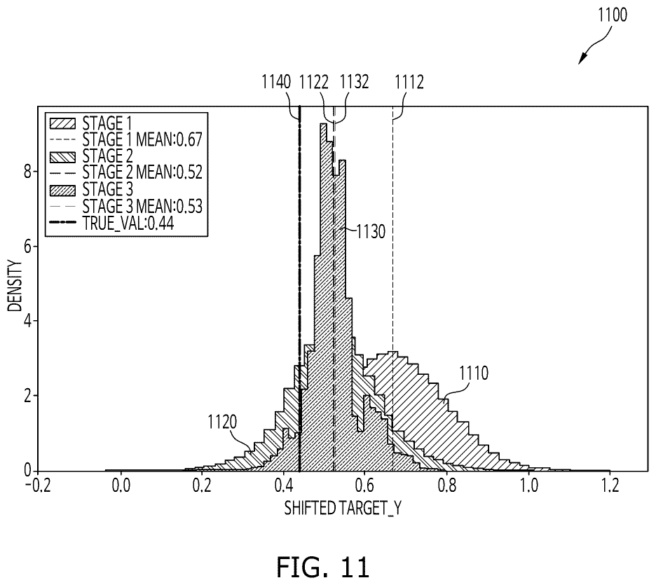

FIG. 11 illustrates an example of a graph 1100 showing a plurality of predicted values according to embodiments of the present disclosure.

Referring to FIG. 11, the graph 1100 shows the results of a simulation that predicted the capacity of a secondary battery using the history data of the secondary battery in a semi-finished state. The horizontal axis of the graph 1100 represents the predicted capacity of the secondary battery, and the vertical axis represents the density of the distribution.

In embodiments, a plurality of predicted values that predict the performance of a secondary battery may be generated for each of a plurality of synthetic data associated with the secondary battery in a semi-finished state. In addition, if an average of the plurality of predicted values that predict the performance of the secondary battery is lower than a predetermined threshold 1140, the corresponding secondary battery may be determined to be defective.

Referring to the graph 1100, a first distribution 1110 represents a plurality of predicted values that predict the performance of a secondary battery, generated based on synthetic data associated with the secondary battery in a semi-finished state up to a first process (e.g., an electrode manufacturing process). A second distribution 1120 represents a plurality of predicted values that predict the performance of a secondary battery, generated based on synthetic data associated with the secondary battery in a semi-finished state up to the first process and a second process (e.g., an assembly process). A third distribution 1130 represents a plurality of predicted values that predict the performance of a secondary battery, generated based on synthetic data associated with the secondary battery in a semi-finished state up to the first process, the second process, and a third process (e.g., a formation process). It can be confirmed that an average 1122 of the second distribution 1120 and an average 1132 of the third distribution 1130 are located closer to the predetermined threshold 1140 than an average 1112 of the first distribution 1110. As the manufacturing process of the secondary battery proceeds, the accuracy of the performance prediction for the secondary battery may improve.

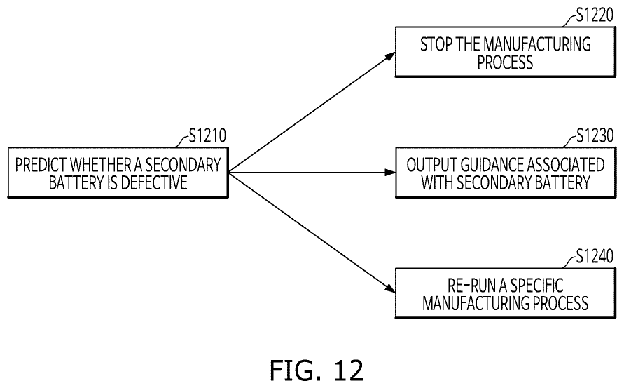

FIG. 12 illustrates an example of a response method when it is determined that a secondary battery is defective according to embodiments of the present disclosure.

In embodiments, as described herein with reference to FIGS. 8 and 10, a processor (e.g., 334 of FIG. 3) may predict whether a secondary battery is defective when the manufacturing of the secondary battery in a semi-finished state is completed (S1210). The processor may determine whether to proceed with a manufacturing process after a specific manufacturing process of the secondary battery based on the predicted defect status of the secondary battery. For example, if a secondary battery in a semi-finished state has progressed up to a first process but is predicted to be defective, the processor may determine to stop the manufacturing process after the first process for the corresponding secondary battery (S1220). In this case, the corresponding secondary battery may be discarded. Conversely, if a secondary battery in a semi-finished state has progressed up to the first process and is predicted to be normal, the processor may determine to proceed with the manufacturing process after the first process for the corresponding secondary battery.

In embodiments, if the processor predicts that a secondary battery in a semi-finished state will be defective, the processor may output guidance associated with the corresponding secondary battery (S1230). Here, the guidance associated with the secondary battery may include at least one of identification data, location data, manufacturing process data, quality data of the secondary battery, data associated with equipment for manufacturing the secondary battery, or data associated with the manufacturing environment of the secondary battery.

In embodiments, if the processor predicts that a secondary battery in a semi-finished state will be defective, the processor may determine to re-run a specific manufacturing process for the corresponding secondary battery (S1240). For example, if a secondary battery in a semi-finished state has undergone a formation process but is predicted to be defective, the processor may determine to re-run the formation process for the corresponding secondary battery.

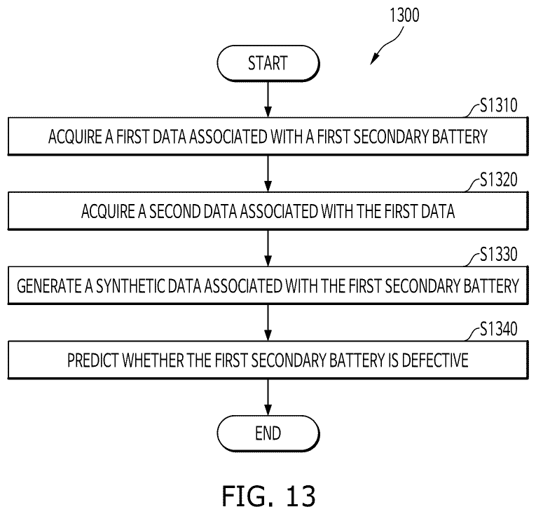

FIG. 13 is a flowchart illustrating an example of a method for predicting defects in a secondary battery 1300 according to embodiments of the present disclosure. In embodiments, the method for predicting defects in a secondary battery 1300 may be performed by at least one processor (e.g., 334 of FIG. 3). The method for predicting defects in a secondary battery 1300 may begin with the processor acquiring a first data associated with a first secondary battery that has progressed up to a specific manufacturing process among a plurality of manufacturing processes for manufacturing the secondary battery (S1310). Here, the first data may include data up to the specific manufacturing process. In addition, the plurality of manufacturing processes may include at least one of an electrode manufacturing process, an assembly process, or a formation process.

Thereafter, the processor may acquire a second data associated with the first data (S1320). Here, the second data may include data after the specific manufacturing process. In addition, the second data may include at least a portion of data associated with a second secondary battery that is different from the first secondary battery.

Thereafter, the processor may generate a synthetic data associated with the first secondary battery based on the first data and the second data (S1330). In addition, the processor may predict whether the first secondary battery is defective based on the synthetic data using a machine learning model (S1340).

In embodiments, the data associated with the second secondary battery may include a first history data up to the specific manufacturing process of the second secondary battery and a second history data after the specific manufacturing process of the second secondary battery. In this case, the processor may compare the first data with the first history data. In addition, based on a result of comparing the first data and the first history data, the processor may acquire the second history data as the second data.

In embodiments, the first secondary battery may correspond to a secondary battery in a semi-finished state, and the second secondary battery may correspond to a secondary battery in a finished state. In addition, the second data may include data associated with a plurality of secondary batteries that have undergone all of the plurality of manufacturing processes. Additionally, the first data may include at least one of data associated with the quality of the first secondary battery up to the specific manufacturing process or data associated with the manufacturing environment of the first secondary battery.

In embodiments, the machine learning model may be trained to take synthetic data associated with a secondary battery as input and predict and output whether the secondary battery is defective. In addition, the machine learning model may correspond to a model trained on a dataset including data associated with a secondary battery that has undergone all of the plurality of manufacturing processes and information on whether the secondary battery is defective.

In embodiments, the synthetic data may include a plurality of synthetic data associated with the first secondary battery. In this case, the processor may use the machine learning model to generate a plurality of predicted values associated with whether the first secondary battery is defective for each of the plurality of synthetic data. In addition, the processor may determine whether the first secondary battery is defective based on the plurality of predicted values. Specifically, the processor may determine that the first secondary battery is defective if an average of the predicted values that predict the first secondary battery is defective among the plurality of predicted values is higher than a predetermined threshold.

In embodiments, the machine learning model may be trained to take synthetic data associated with a secondary battery as input, predict the performance of the secondary battery, and output data associated with the performance of the secondary battery. In this case, the processor may use the machine learning model to generate a plurality of predicted values that predict the performance of the first secondary battery for each of the plurality of synthetic data. In addition, the processor may determine whether the first secondary battery is defective based on the plurality of predicted values.

In embodiments, each of the plurality of predicted values may include a value predicting the capacity of the first secondary battery for each of the plurality of synthetic data. In this case, the processor may determine that the first secondary battery is defective if an average of the plurality of predicted values that predict the capacity of the first secondary battery is lower than a predetermined threshold.

In embodiments, the processor may determine whether to proceed with a manufacturing process after the specific manufacturing process of the first secondary battery based on the predicted defect status of the first secondary battery. In addition, if the processor predicts that the first secondary battery will be defective, the processor may provide guidance associated with the first secondary battery. Additionally, in response to predicting that the first secondary battery will be defective, the processor may determine to re-run the specific manufacturing process for the first secondary battery.

The herein-described method may be provided as a computer program stored on a computer-readable recording medium for execution on a computer. The medium may continuously store a computer-executable program, or temporarily store it for execution or download. In addition, the medium may be various recording means or storage means in the form of a single or several pieces of hardware combined, but is not limited to a medium directly connected to a computer system, and may be distributed on a network. Examples of the medium may include magnetic media such as hard disks, floppy disks, and magnetic tapes, optical recording media such as CD-ROMs and DVDs, magneto-optical media such as floptical disks, and those configured to store program instructions, including ROM, RAM, flash memory, etc. In addition, other examples of the medium may include recording media or storage media managed by app stores that distribute applications or sites and servers that supply or distribute various other software.

The methods, operations, or techniques of the present disclosure may be implemented by various means. For example, these techniques may be implemented in hardware, firmware, software, or a combination thereof. Those of ordinary skill in the art will understand that the various exemplary logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described herein generally in terms of their functionality. Whether such functionality is implemented as hardware or software depends upon the particular application and design constraints imposed on the overall system. Those of ordinary skill in the art may implement the described functionality in varying ways for each particular application, but such implementation decisions should not be interpreted as causing a departure from the scope of the present disclosure.

In a hardware implementation, the processing units used to perform the techniques may be implemented within one or more ASICs, DSPs, GPUs, digital signal processing devices (DSPDs), programmable logic devices (PLDs), field programmable gate arrays (FPGAs), processors, controllers, microcontrollers, microprocessors, electronic devices, other electronic units designed to perform the functions described in the present disclosure, a computer, or a combination thereof.

Accordingly, the various exemplary logical blocks, modules, and circuits described in connection with the present disclosure may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In a firmware and/or software implementation, the techniques may be implemented as instructions stored on a computer-readable medium, such as random access memory (RAM), read-only memory (ROM), non-volatile random access memory (NVRAM), programmable read-only memory (PROM), erasable programmable read-only memory (EPROM), electrically erasable PROM (EEPROM), flash memory, a compact disc (CD), magnetic or optical data storage devices, etc. The instructions may be executable by one or more processors and may cause the processor(s) to perform certain aspects of the functionality described in the present disclosure.

If implemented in software, the techniques may be stored on or transmitted over as one or more instructions or code on a computer-readable medium. Computer-readable media include both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium.

For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the herein should also be included within the scope of computer-readable media.

A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

Although the embodiments described herein have been described as utilizing aspects of the presently disclosed subject matter in one or more standalone computer systems, the present disclosure is not limited thereto and may be implemented in connection with any computing environment, such as a network or distributed computing environment. Further, aspects of the subject matter in the present disclosure may be implemented in a plurality of processing chips or devices, and storage may be similarly affected across a plurality of devices. Such devices may include PCs, network servers, and portable devices.

Although the present disclosure has been described herein with respect to embodiments thereof, the present disclosure is not limited thereto. Various modifications and variations can be made thereto by those skilled in the art within the spirit of the present disclosure and the equivalent scope of the appended claims.

What is claimed is:

1. A method for predicting defects in a secondary battery, the method comprising:
acquiring first data associated with a first secondary battery that has progressed up to a specific manufacturing process among a plurality of manufacturing processes for manufacturing a secondary battery;
acquiring second data associated with the first data;
generating synthetic data associated with the first secondary battery based on the first data and the second data; and
predicting whether the first secondary battery is defective based on the synthetic data using a machine learning model,
wherein:
the first data comprises data up to the specific manufacturing process, and
the second data comprises data after the specific manufacturing process.

2. The method for predicting defects in a secondary battery as claimed in claim 1, wherein the second data comprises at least a portion of data associated with a second secondary battery that is different from the first secondary battery.

3. The method for predicting defects in a secondary battery as claimed in claim 2, wherein the data associated with the second secondary battery comprises first history data up to the specific manufacturing process of the second secondary battery and second history data after the specific manufacturing process of the second secondary battery, and
acquiring the second data comprises:
comparing the first data and the first history data; and
acquiring the second history data as the second data based on a result of comparing the first data and the first history data.

4. The method for predicting defects in a secondary battery as claimed in claim 2, wherein the first secondary battery corresponds to a secondary battery in a semi-finished state, and the second secondary battery corresponds to a secondary battery in a finished state.

5. The method for predicting defects in a secondary battery as claimed in claim 1, wherein the second data comprises data associated with a plurality of secondary batteries that have undergone all of the plurality of manufacturing processes.

6. The method for predicting defects in a secondary battery as claimed in claim 1, wherein the first data comprises at least one of data associated with a quality of the first secondary battery up to the specific manufacturing process or data associated with a manufacturing environment of the first secondary battery.

7. The method for predicting defects in a secondary battery as claimed in claim 1, wherein the plurality of manufacturing processes comprises at least one of an electrode manufacturing process, an assembly process, or a formation process.

8. The method for predicting defects in a secondary battery as claimed in claim 1, wherein the machine learning model is trained to predict and output whether the secondary battery is defective, with synthetic data associated with the secondary battery as input.

9. The method for predicting defects in a secondary battery as claimed in claim 1, wherein the machine learning model corresponds to a model trained on a dataset comprising data associated with a secondary battery that has undergone all of the plurality of manufacturing processes and information on whether the secondary battery is defective.

10. The method for predicting defects in a secondary battery as claimed in claim 1, wherein the synthetic data comprises a plurality of synthetic data associated with the first secondary battery, and
predicting whether the first secondary battery is defective comprises:
generating, using the machine learning model, a plurality of predicted values associated with whether the first secondary battery is defective for each of the plurality of synthetic data; and
determining whether the first secondary battery is defective based on the plurality of predicted values.

11. The method for predicting defects in a secondary battery as claimed in claim 10, wherein determining whether the first secondary battery is defective comprises:
determining the first secondary battery to be defective when an average of predicted values that predict the first secondary battery is defective among the plurality of predicted values is higher than a predetermined threshold.

12. The method for predicting defects in a secondary battery as claimed in claim 1, wherein the machine learning model is trained to predict a performance of the secondary battery and output data associated with the performance of the secondary battery, with synthetic data associated with the secondary battery as input.

13. The method for predicting defects in a secondary battery as claimed in claim 1, wherein the synthetic data comprises a plurality of synthetic data associated with the first secondary battery, and
predicting whether the first secondary battery is defective comprises:
generating, using the machine learning model, a plurality of predicted values that predict a performance of the first secondary battery for each of the plurality of synthetic data; and
determining whether the first secondary battery is defective based on the plurality of predicted values.

14. The method for predicting defects in a secondary battery as claimed in claim 13, wherein each of the plurality of predicted values comprises a value that predicts a capacity of the first secondary battery for each of the plurality of synthetic data.

15. The method for predicting defects in a secondary battery as claimed in claim 14, wherein determining whether the first secondary battery is defective comprises:
determining the first secondary battery to be defective when an average of the plurality of predicted values that predict the capacity of the first secondary battery is lower than a predetermined threshold.

16. The method for predicting defects in a secondary battery as claimed in claim 1, further comprising:
determining whether to proceed with a manufacturing process after the specific manufacturing process of the first secondary battery based on the predicted defect status of the first secondary battery.

17. The method for predicting defects in a secondary battery as claimed in claim 1, further comprising:
providing guidance associated with the first secondary battery when it is predicted that the first secondary battery will be defective.

18. The method for predicting defects in a secondary battery as claimed in claim 1, further comprising:
determining to re-run the specific manufacturing process for the first secondary battery in response to predicting that the first secondary battery will be defective.

19. A computer program stored on a computer-readable recording medium for executing the method according to claim 1 on a computer.

20. An apparatus, comprising:
a communication module;
a memory; and
at least one processor connected to the memory and configured to execute at least one computer-readable program included in the memory,
wherein the at least one program comprises instructions for:
acquiring first data associated with a first secondary battery that has progressed up to a specific manufacturing process among a plurality of manufacturing processes for manufacturing a secondary battery,
acquiring second data associated with the first data,
generating synthetic data associated with the first secondary battery based on the first data and the second data, and
predicting whether the first secondary battery is defective based on the synthetic data using a machine learning model,
wherein:
the first data comprises data up to the specific manufacturing process, and
the second data comprises data after the specific manufacturing process.
